(19) United States
(12) Patent Application Publication
(10) Pub. No.: US 2005/0000820 A1
(43) Pub. Date: Jan. 6, 2005

(54) Apparatus and method for processing a substrate

(76) Inventors: Koji Mishima, Tokyo (JP); Kunihito Ide, Tokyo (JP); Hidenao Suzuki, Tokyo (JP); Kazufumi Nomura, Tokyo (JP); Hiroyuki Kanda, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/854,252

(22) Filed: May 27, 2004

(30) Foreign Application Priority Data
May 30, 2003 (JP) 2003-154809

(51) Int. Cl. C25D 17/00; H01L 21/445; C25C 7/00

(52) U.S. Cl. 205/118; 205/80; 205/123; 204/252; 204/275.1

(57) ABSTRACT

A method and apparatus are set forth capable of processing a substrate with a high uniformity within the surface area even for a thin feeding layer. The method comprises arranging a counter electrode and the substrate to confront each other; providing a membrane between the counter electrode and the substrate to define a substrate side region and a counter electrode side region. The substrate side region and the counter electrode side region are capable of accommodating respective electrolytes. The substrate side region and the counter electrode side region are supplied with respective electrolytes having different specific resistances. A processing current is also supplied between the substrate and the counter electrode.

### BACKGROUND OF THE INVENTION

1. Field of the Invention

The present invention relates to a method and apparatus for processing a substrate, and more specifically to a process and apparatus for electrolytically processing a substrate, such as electroplating interconnect materials such as copper on a surface of the substrate formed with fine interconnect patterns for thereby forming LSI interconnects, or removing a metal film formed on the surface by an electrolytic etching process.

2. Description of the Related Art

Lately, as for an interconnect material for forming electric interconnections on a semiconductor substrate, copper having a low electric resistance and a high anti-electromigration property is replacing aluminum or aluminum alloys. Since it is difficult to form copper into an interconnect shape through a conventional anisotropic etching, which is effective for aluminum, copper interconnects are formed through a process called a “copper damascene technology” in which copper is filled inside fine recesses formed on the substrate surface. Other methods such as chemical vapor deposition (CVD) or sputtering may deposit a copper film on the whole surface of the substrate, and requires removing of unnecessary portion of copper through a chemical mechanical planarization (CMP) process or electrolytic etching process.

FIG. 5 shows a flowchart for a conventional manufacturing process of the above described substrate W having the copper interconnects. In the first place, as shown in FIG. 5(a), a substrate W comprising a semiconductor base 1 formed with semiconductor devices or elements is prepared, on which an oxide film 2 made of SiO₂ is deposited on a conductor layer la, fine recesses for interconnect such as via holes 3 or interconnect trenches 4 are formed by a lithographic etching process, a barrier layer 5 made of TaN or the like is formed thereon, and a seed layer 7 is further formed on the barrier layer 5 as a feeder layer for electroplating.

By plating copper on the surface of the substrate W, as shown in FIG. 5(b), a copper film 6 fills the via holes 3 or interconnect trenches 4 as well as covers the surface of the oxide film 2. Then, the copper film 6 and barrier layer 5 on the oxide film 2 is removed by the CMP or electrolytic etching process to substantially level the surface of the copper film 6 filling the via holes 3 and interconnect trenches 4 with the exposed surface of the oxide film 2. Thus, the interconnect made of the copper film 6 is formed.

As described above, as aluminum is replaced by copper for the interconnect material, apparatuses for electroplating copper films or electrolytically etching copper films has been catching eyes of the industry.

When forming a copper interconnect using a copper sulfide solution or a copper complex solution as plating solution and the substrate W as a cathode, a soluble anode is generally used such as an electrolytic copper or a phosphorus containing copper.

FIG. 6 shows a general assembly of the above mentioned conventional copper plating apparatus employing a so-called “face-up” design. This plating apparatus comprises an electroplating unit 10, and a plating solution supply system 12 for supplying and recovering an electrolyte as a plating solution to and from the electroplating unit 10. The electroplating unit 10 comprises: a substrate holder 14 arranged elevatable and rotatable for detachably supporting a substrate W with the surface facing upward; a bath forming member 16 shaped in a tapered hollow cylinder and assembled on the periphery of the substrate W supported by the substrate holder 14 to surround a space on the substrate W; and an electrode head 18 arranged elevatable, rotatable, and located above the substrate holder 14.

The bath forming member 16 has a smaller outer diameter at the lower end than the substrate W, and a top inner diameter larger than both the lower end thereof and the outer diameter of the electrode head 18 (the outer diameter of the porous member 22 described below). A seal portion is formed between the lower end of the bath forming member 16 and the substrate surface during operation to make a plating bath in a region (substrate side region) defined by the bath forming member 16 and the substrate surface.

The electrode head 18 comprises a housing 26 having a open lower end covered by a porous member or diaphragm 22 for defining an anode chamber 24 within the housing 26, in which an anode 20 is accommodated. A power source 28 for supplying plating current between the seed layer 7 (shown in FIG. 5(a)) formed on a surface of the substrate W held by the substrate holder 14 and the anode 20.

The plating solution supply system 12 is for reserving and supplying a plating solution (electrolyte) Q such as a copper sulfide plating solution, for example, and comprises: a reservoir tank 30; a couple of plating solution supply lines 32, 34 extending from the reservoir tank 30 and connected to the electroplating unit; and a couple of plating solution discharge lines 36, 38 for returning the plating solution from the electroplating unit 10 to the reservoir tank 30. The plating solution supply system 12 supplies the same plating solution from the reservoir tank 30 to a substrate side region which is defined between the substrate W and the porous member 22 and to an anode side region defined inside the anode chamber 24, and returns the plating solution discharged from those regions to the reservoir tank 30.

Thus, a self-controlled system is constructed capable of automatically supplying copper ions at the anode side region to compensate copper ions decreased at the substrate side region. Supply lines may be provided individually for both regions but discharged lines are returned to the same tank. The plating apparatus is mostly operated using an insoluble anode as the anode 20. It can be also used with soluble anode which is isolated with a porous membrane called an “anode bag”.

FIG. 7 shows another conventional plating apparatus employing a so-called “face-down” design. This plating apparatus comprises an electrolytic plating unit 40 having a substrate holder 42 elevatable and rotatable for detachably supporting a substrate W with the surface facing downward, and a plating vessel 44 for accommodating a plating solution, which are arranged in an above-and-below relationship. Inside the plating vessel 44, an anode chamber 50 is defined which is circumferentially partitioned by a separation wall 46 and covered atop with a porous membrane, in which an anode 52 is arrange as a counter electrode to the substrate W at a position to confront the substrate W. Other structures are similar to the apparatus shown in FIG. 6. This apparatus also provides a self-controlled system for automatically supplying copper ions at the counter electrode side region to compensate those decreased at the substrate side region.

As the LSIs are highly integrated, metal films such as the seed layer or a feeder layer has become progressively thin for an electrolytic processing process such as an electroplating or electrolytically etching process. As the feeder layer becomes thinner, variance of plating potential within the surface area of the substrate W becomes larger. Therefore, as shown in FIG. 6, a thickness of the plating film becomes larger at a position close to the feeding point to the substrate W, and becomes progressively thin at positions away from the feeding point, that is, close to the center of the substrate W. This means that uniformity of the plating characteristics within the surface area of the substrate W is lowered, and that an effective surface area or a device field ratio has become decreased for the substrate W. In the electrolytic etching process, as shown in FIG. 8, an etching rate is large at a position close to the feeding point and smaller at positions away from the feeding point.

The present invention has been accomplished to solve the above described problems, and an object of the invention is to provide a method and apparatus for electrolytically processing a substrate in which the deposition or etching can be performed with a high uniformity within the surface area even for a thin feeding layer.

### SUMMARY OF THE INVENTION

According to one aspect of the present invention, a method for processing a substrate comprises: arranging a counter electrode and the substrate to confront each other; providing a membrane between the counter electrode and the substrate to define a substrate side region and a counter electrode side region, the substrate side region and the counter electrode side region capable of accommodating respective electrolytes; supplying the substrate side region and the counter electrode side region with respective electrolytes having different specific resistances; and supplying a processing current between the substrate and the counter electrode.

By supplying the counter electrode side region partitioned by the membrane with an electrolyte having a possible maximum specific resistance, and the substrate side region with a normal process electrolyte, processing of the substrate can be performed with a high uniformity within the surface area of the substrate even for a thin feeder layer with indefinitely high resistance. The electrolyte supplied to the anode side region may be provided only with a function as an electrolyte capable of conducting electricity so that processing ability is not lowered.

The membrane may comprise at least one of a porous membrane, a porous structural member, and an ion exchange membrane. The porous membrane or porous structural member comprises mutually communicating fine pores capable of maintaining electrolyte. Specifically, the porous member may be made of but is not limited to: a sintered compact of polyethylene or polypropylene; a laser worked porous member made of a Teflon (trade name) etc.; porous ceramics; sponges; and woven or non woven fabrics.

The substrate may be formed with fine interconnect recesses for receiving a metal material through plating, and a feeder layer for feeding the substrate with a plating current, and the fine interconnect recesses has a width not more than 0.3 μm and the feeder layer has a thickness not more than 0.05 μm. The present invention is particularly effective for the feeder layer as thin as not more than 0.05 μm, when plating copper interconnections in an LSI, for example. The interconnections here are extremely fine with a width of not more than 0.3 μm.

The substrate maybe set as an anode, and the counter electrode may be set as a cathode to electroplate copper to the substrate, and the electrolyte supplied to the counter electrode side region may have a larger specific resistance than the electrolyte supplied to the substrate side region. As for the electrolyte supplied to the counter electrode side region, a dilute sulfuric acid is exemplified. It may comprise but not limited to other solutions such as an aqueous solution of copper sulfide, or a mixed solution of copper sulfide and a dilute sulfuric acid.

The electrolyte supplied to the counter electrode side region may be a copper free electrolyte solution.

The counter electrode may comprise an insoluble material. Although the invention is particularly effective when using an insoluble material as the counter electrode, soluble materials is applicable.

According to another aspect of the present invention, an apparatus for processing a substrate comprises: a vessel for accommodating the substrate; a counter electrode arranged to confront the substrate; a membrane arranged between the counter electrode and the substrate to define a substrate side region and a counter electrode side region, the substrate side region and the counter electrode side region capable of accommodating respective electrolytes; electrolyte supply systems for respectively supplying the substrate side region and the counter electrode side region with respective electrolytes having different specific resistances; and a power source for supplying a processing current between the substrate and the counter electrode.

The membrane may comprise at least one of a porous membrane, a porous structural member, and an ion exchange membrane.

The electrolyte supply system for supplying the electrolyte to the counter electrode side region may comprise a specific resistance detector for detecting specific resistance of electrolyte and a specific resistance adjuster for adjusting specific resistance of electrolyte based on an output of the specific resistance detector. It is possible to provide an electrolyte of a regularly controlled constant specific resistance to the counter electrode side region.

The substrate may be set as a cathode, and the counter electrode may be set as an anode, and the counter electrode may comprise a mesh-like member made of an insoluble material.

The apparatus may further comprise a gas discharge line for discharging a gas generated at the anode. It is possible to prevent the oxygen gas from reaching the substrate to generate particles.

### BRIEF DESCRIPTION OF THE DRAWINGS

FIG. 1 is a schematic diagram showing an electrolytic processing apparatus according to an embodiment of the present invention applied to an electroplating apparatus;

FIG. 2 shows a graph of a relationship between a location in the substrate surface and a film thickness for a plating process using the apparatus shown in the FIG. 1 and a conventional apparatus;

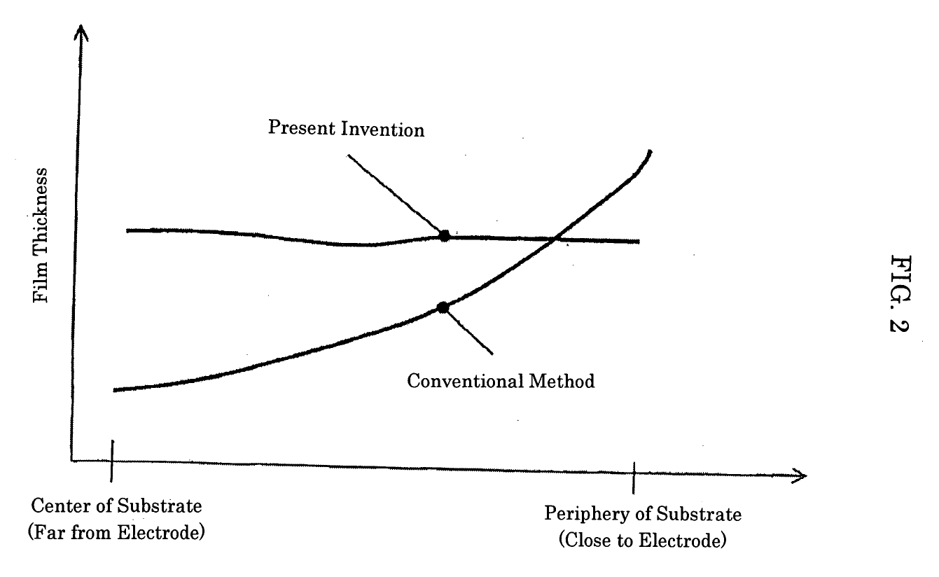

FIG. 3 shows a schematic diagram of an electrolytic processing apparatus according to another embodiment of the present invention applied to an electrolytic etching apparatus;

FIG. 4 shows a schematic diagram of an electrolytic processing apparatus according to another embodiment of the present invention applied to an electroplating apparatus;

FIG. 5 is a schematic diagram of showing a process of forming a copper interconnect;

FIG. 6 is a schematic diagram showing the conventional electroplating apparatus;

FIG. 7 is a schematic diagram showing another conventional electroplating apparatus; and

FIG. 8 shows a graph showing a relationship between the plated film thickness and a location within the substrate surface when plating and etching by using conventional apparatus.

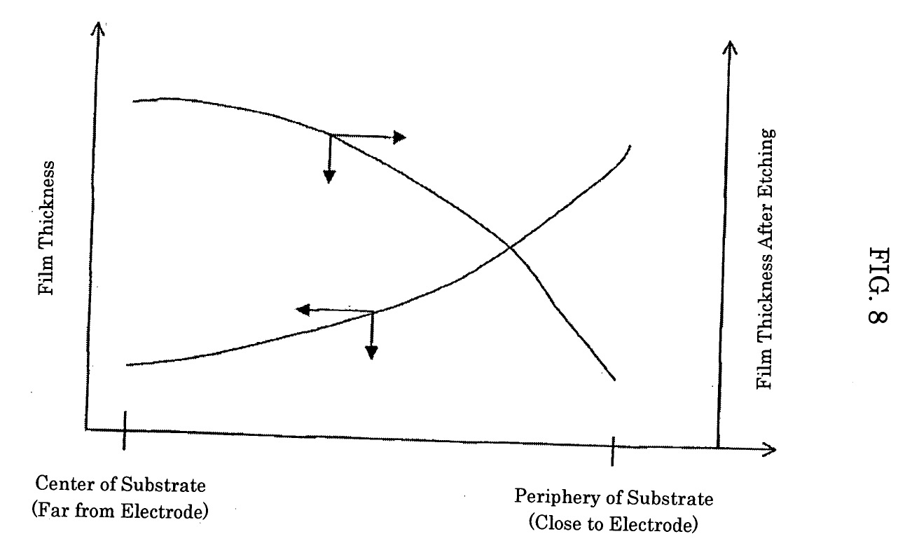

### DETAILED DESCRIPTION OF THE PREFERRED EMBODIMENTS

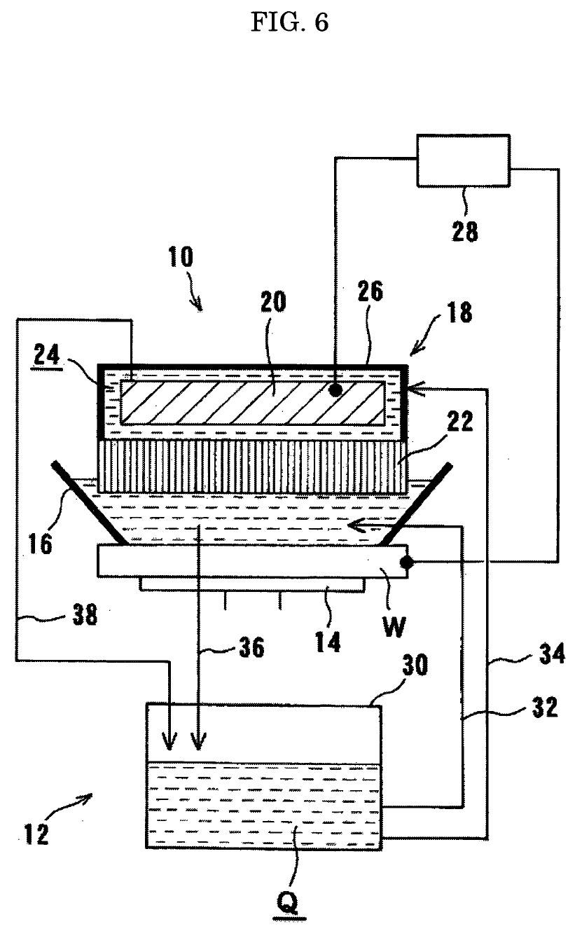

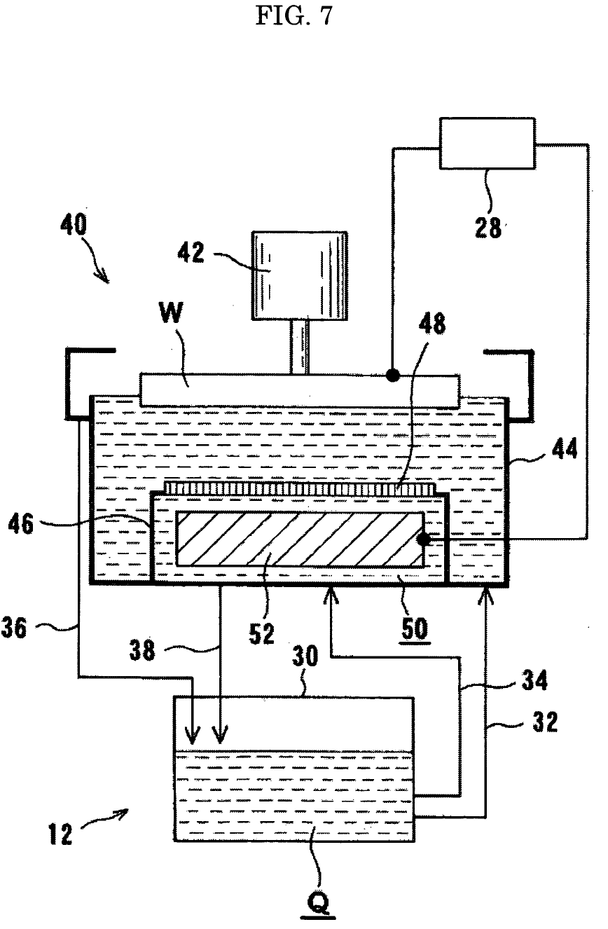

The embodiment of the present invention will be described with reference to the attached drawings. The same or corresponding structures with those in the conventional apparatus shown in FIG. 6 or FIG. 7 are designated with the same numerals and the explanation will be omitted.

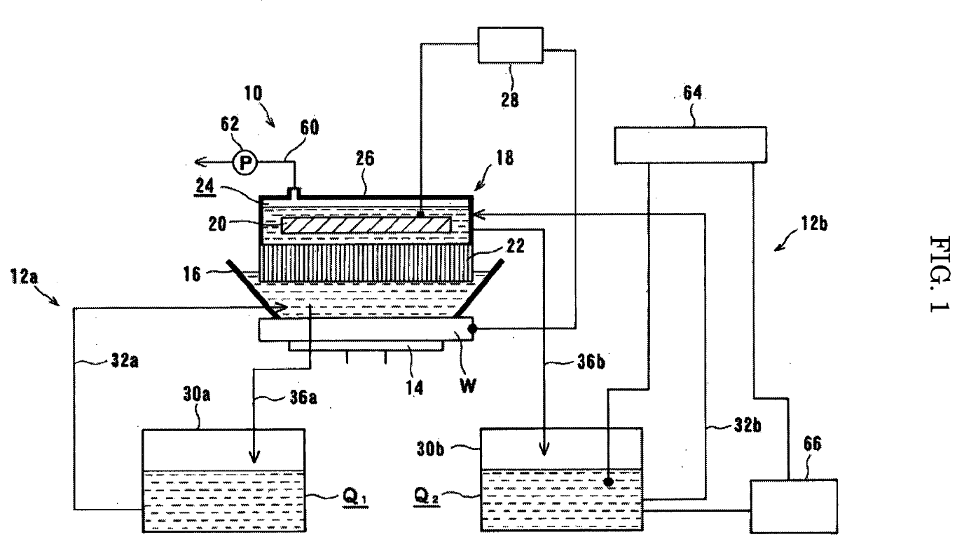

FIG. 1 shows an electrolytic processing apparatus according to an embodiment of the present invention applied to an electroplating apparatus. As shown in FIG. 1, the plating apparatus comprises an electroplating unit 10 and a couple of electrolyte supply systems 12a, 12b for supplying and recovering an electrolyte to and from the electroplating unit 10.

The electroplating unit 10 comprises a substrate holder 14, a bath forming member 16 shaped in a tapered hollow cylinder, and an electrode head 18. The bath forming member 16 has a smaller outer diameter at the lower end than the substrate W, and a top inner diameter larger than both the lower end thereof and the outer diameter of the electrode head 18 (the outer diameter of the porous member 22 described below). A seal portion is formed between the lower end of the bath forming member 16 and the substrate surface during operation to make a plating bath in a region (substrate side region) defined by the bath forming member 16 and the substrate surface.

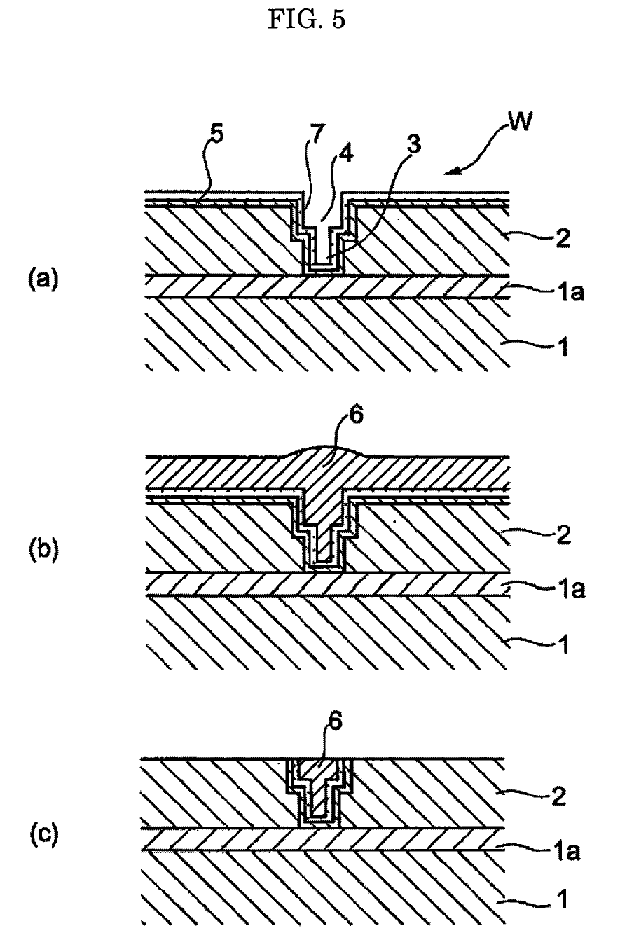

The electrode head 18 comprises a housing 26 having a open lower end covered by a porous member or diaphragm 22 for defining an anode chamber 24 within the housing 26, in which an anode 20 is accommodated. A power source 28 for supplying plating current between the seed layer 7 (shown in FIG. 5(a)) formed on a surface of the substrate W held by the substrate holder 14 and the anode 20.

The porous member 22 is made of a porous membrane or a porous structural member in the embodiment and can be replaced by an ion exchange membrane. The porous membrane or porous structural member comprises mutually communicating fine pores capable of maintaining electrolyte. Specifically, the porous member 22 may be made of but is not limited to: a sintered compact of polyethylene or polypropylene; a laser worked porous member made of a Teflon (trade name) etc.; porous ceramics; sponges; and woven or non woven fabrics.

One of the electrolyte supply systems 12a is for supplying a plating solution (processing liquid) Q1 such as a copper sulfide plating solution to a substrate side region, which is defined between the substrate W held by the substrate holder 14 and the porous member 22. The electrolyte supply systems 12a comprises: a reservoir tank 30a for accommodating a plating solution Q1; a plating solution supply line 32a and a plating solution discharge line 36a extending from the reservoir tank 30a and connected to the substrate side region.

Another electrolyte supply system 12b is for supplying an electrolyte solution (electrolyte) Q2 free of copper such as a dilute sulfuric acid to an anode side region (counter electrode side region), which is partitioned by the porous member 22 and defined within the anode chamber 24. The electrolyte supply system 12b comprises: a reservoir tank 30b for accommodating an electrolyte solution Q2; a plating solution supply line 32b and a plating solution discharge line 36a extending from the reservoir tank and connected to the housing 26.

The electrolyte Q2 has a specific resistance (electric conductivity) ρ2 larger than the specific resistance 1 of the plating solution Q1, as expressed by ρ2>ρ1.

The anode 20 is comprised of a mesh-like member made of an insoluble material such as an insoluble metal such as platinum or titanium, or a base metal plated with platinum etc. such as a titanium mesh plate coated with iridium oxide, for example. By using the insoluble electrode, there is no need of exchanging the electrode, and by using the mesh-like member, the plating solution or generated gases can flow through the electrode.

When using an insoluble material for the anode 20, oxygen gas is generated at the surface of the anode 20 during operation. A gas discharge line 60 is connected to the top wall of the housing 26, in this embodiment, for exhausting accumulated gases in the anode chamber 24, which is provided with a vacuum pump 62. The vacuum pump evacuates the oxygen gas to prevent it from reaching the substrate W to generate particles. The pressure within the anode chamber 24 is preferably controlled at a preset value by a feedback control within the process.

In the electrolyte supply system 12b, a specific resistance detector 64 for detecting the specific resistance of the electrolyte Q2 within the reservoir tank 30b and a specific resistance adjuster 66 for adjusting the specific resistance of electrolyte Q2 based on the detected signal by the specific resistance detector 64 are provided. These devices make it possible to provide an electrolyte Q2 of a regularly controlled constant specific resistance to the interior (counter electrode side region) of the anode chamber 24. When plating copper, a 0.03-0.05% phosphorus containing copper can be used as the anode 20 to suppress generation of slimes.

One exemplified process using the electroplating apparatus is described for filling copper in via holes 3 and interconnect trenches 4 formed on a surface of the substrate W as shown in FIG. 5(a) and FIG. 5(b).

In the first place, as shown in FIG. 5(a), the substrate W is prepared, on which fine recesses for interconnect such as via holes 3 or interconnect trenches 4 are formed in the oxide film 2, and a barrier layer 5 made of TaN etc. and a seed layer 7 as a feeder layer for electroplating are formed in turn. Since the present invention is particularly effective for the seed layer as thin as not more than 0.05 μm, when plating copper interconnections in an LSI, for example. The interconnections here are extremely fine with a width of not more than 0.3 μm (shown in FIG. 6(c)).

The substrate W is supported by the substrate holder 14 with the surface facing upward and is elevated to a position at which the periphery of the substrate W is made to pressure contact with the bath forming member 16 to liquid tightly seal there. The electrode head 18 readily accommodating the electrolyte solution Q2 within the anode chamber 24 is lowered until the distance between the upper (front) surface of the substrate W and the lower surface of the porous member 22 is a predetermined value.

At this state, a predetermined amount of plating solution Q1 is supplied or circulated to the substrate side region defined between the substrate W and the electrode head 18 and surrounded by the bath forming member 16. At the same time, the electrolyte Q2 contained in the anode side region partitioned by the porous member 22 within the anode chamber 24 is supplied to the area above the substrate W by pressurizing inside the anode chamber 24 or releasing the air tightness of the anode chamber 24. By applying a plating voltage between the seed layer 7 of the substrate W and the anode 20 with the power source 28 to supply plating current and by rotating the substrate W together with electrode head 18 as is necessary, electroplating is performed on the surface of the substrate W.

As described above, the anode side region (counter electrode side region) partitioned by the porous member 22 is supplied with the electrolyte Q2 with a maximum specific resistance ρ2 as possible, and by supplying the substrate side region with an ordinary plating solution Q1, it is possible to uniformly plate the substrate W even the seed layer 7 has a resistance indefinitely high. Therefore, while the conventional process provides a larger thickness film at the periphery close to the feed point than the central area, the present invention can deposit a uniform thickness film on the whole surface of the substrate W. Thus, the present invention can enhance uniformity within the surface area to prevent decrease of an effective surface area or device field ratio within the substrate surface.

The electrolyte Q2 supplied to the anode side region may be provided only with a function as an electrolyte capable of conducting electricity so that the throughput or processing ability of the plating apparatus is not lowered.

After plating a predetermined time to fill copper within the via holes or interconnect trenches 4 as well as to deposit a copper film 6 on the oxide film 2, application of plating voltage between the seed layer 7 and anode 20 is stopped to finish the plating process. Then, the electrode head 18 is elevated, the substrate holder 14 is lowered, and the substrate surface after plating is cleaned with deionized water etc. and is dried. Then, the substrate W is transferred to the next process stage.

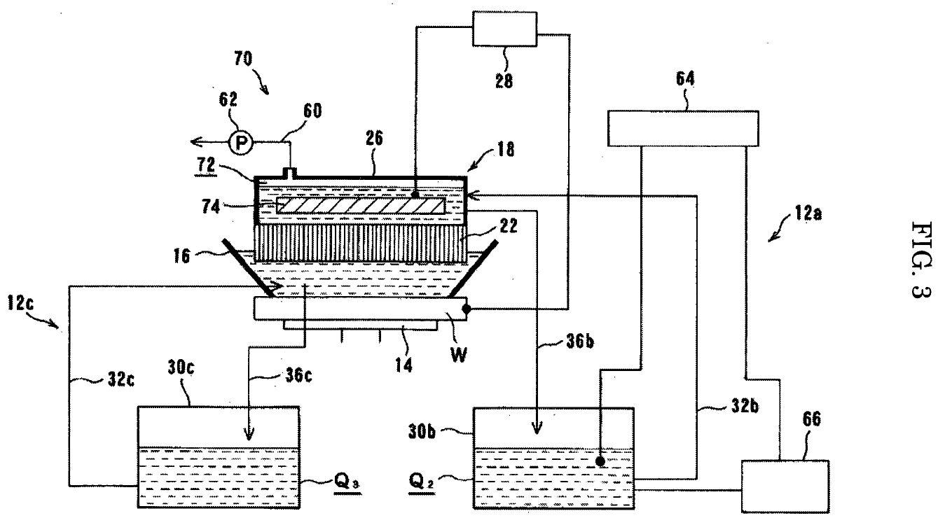

FIG. 3 shows another embodiment of the present invention applied to an electrolytic etching apparatus. The difference between this embodiment and that shown in FIG. 1 is that the electrolyte supply system (plating solution supply system) 12a shown in FIG. 1 is replaced by an electrolyte supply system (etching solution supply system) 12c comprising a reservoir tank 30c, an etching solution supply line 32c, and an etching solution discharge line 36c for supplying etching solution Q3 such as a phosphoric acid solution. Another difference is that the electroplating unit 10 is replaced by an electrolytic etching unit 70 comprising a cathode 74 provided within a cathodic chamber 72 of the electrode head 18, so that power is supplied from the power source 28 between the substrate W as an anode and the cathode 74 to perform etching of the substrate W.

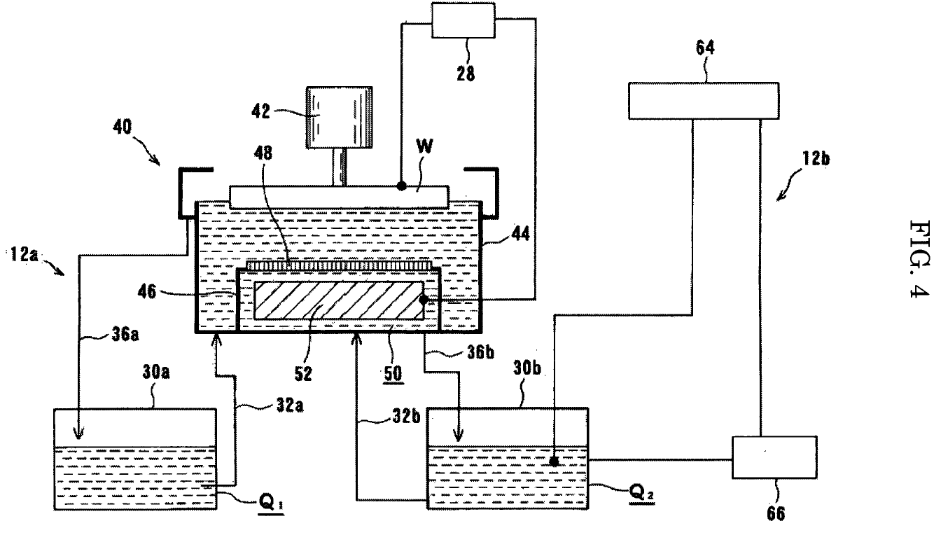

FIG. 4 shows a processing apparatus according to another embodiment of the present invention applied to an electroplating apparatus. The electroplating apparatus utilizes an electroplating unit 40 having a substrate holder 42 and a plating vessel 44 arranged in an above-and-below relationship. Inside the plating vessel 44, an anode chamber 50 is defined which is circumferentially partitioned by a separation wall 46 and covered atop with a porous membrane 48, in which an anode 52 is provided as a counter electrode to confront the substrate W. In the embodiment, a 0.03-0.05% phosphorus containing copper is used as the anode 52 to suppress generation of slimes.

The plating solution Q1 is supplied through the electrolyte supply system 12a into the interior of the plating vessel 44 from the bottom of the region surrounded by the outer wall of the plating vessel 44 and the separation wall 46 of the anode chamber 50, and overflows the plating vessel 44 to return to the reservoir tank 30a through the return line 36a to thereby be circulated. The electrolyte Q2 is supplied to the anode chamber 50 from the reservoir tank 30b through the supply line 32b through the center of the bottom and is discharged from the peripheral area of the bottom of the anode chamber through the discharge line 36b to return to the reservoir tank 30b to be circulated. Other structures are the same as that shown in FIG. 1.

In this embodiment, the substrate W formed with a seed layer 7 as a feeder layer is supported by the substrate holder 42 with the surface facing downward, is lowered below the top of the plating vessel 44 until it covers a part of the top opening of the plating vessel 44, and is halted there.

At this state, the plating solution Q1 is supplied to the substrate side region partitioned by the separation wall 46 and membrane 48, that is, an area within the plating vessel 44 except for the anode chamber 50, via the electrolyte supply system 12a. The electrolyte supply system 12a contains and supplies a plating solution Q1 such as a copper sulfide plating solution. Concurrently, the electrolyte Q2 is supplied and circulated to the anode side region within the anode chamber 50, which is defined by the separation wall 46 and the membrane 48, via the electrolyte supply system 12b. The electrolyte supply system 12b contains and supplies an electrolyte Q2 such as dilute sulfuric acid. At this state, plating voltage is applied by the power source 28 between the seed layer 7 and the anode 52 to supply plating current, and the substrate W is rotated as is necessary, to thereby electroplate the surface of the substrate W. After a predetermined time of operation, plating is finished.

In the above embodiment, copper is used as the interconnect material. However, instead of copper, any copper alloys, silver, or silver alloys can be used.

In the embodiment of the present invention, the counter electrode side region partitioned by the membrane 22, 48 is supplied with an electrolyte having a possible maximum specific resistance, and the substrate side region is supplied with a normal process electrolyte, so that deposition or etching can be performed with a high uniformity within the surface area of the substrate W even for a thin feeder layer 7. Therefore, it can provide a uniform film thickness, uniform interconnect filling properties, or uniform etching properties within the surface area even when processing a substrate W of a large diameter, so that semiconductor devices can be stably manufactured with a high yield.

1. A method for processing a substrate comprising:
arranging a counter electrode and said substrate to confront each other;
providing a membrane between said counter electrode and said substrate to define a substrate side region and a counter electrode side region, said substrate side region and said counter electrode side region capable of accommodating respective electrolytes;
supplying said substrate side region and said counter electrode side region with respective electrolytes having different specific resistances; and
supplying a processing current between said substrate and said counter electrode.

2. The method of claim 1, wherein said membrane comprises at least one of a porous membrane, a porous structural member, and an ion exchange membrane.

3. The method of claim 1, wherein said substrate is formed with fine interconnect recesses for receiving a metal material through plating, and a feeder layer for feeding said substrate with a plating current, said fine interconnect recesses having a width not more than 0.3 μm and said feeder layer having a thickness not more than 0.05 μm.

4. The method of claim 3, wherein said substrate is set as an anode, and said counter electrode is set as a cathode to electroplate copper to said substrate, and wherein said electrolyte supplied to said counter electrode side region has a larger specific resistance than said electrolyte supplied to said substrate side region.

5. The method of claim 4, wherein said electrolyte supplied to said counter electrode side region is a copper free electrolyte solution.

6. The method of claim 1, wherein said counter electrode comprises an insoluble material.

7. An apparatus for processing a substrate comprising:
a vessel for accommodating said substrate;
a counter electrode arranged to confront said substrate;
a membrane arranged between said counter electrode and said substrate to define a substrate side region and a counter electrode side region, said substrate side region and said counter electrode side region capable of accommodating respective electrolytes;
electrolyte supply systems for respectively supplying said substrate side region and said counter electrode side region with respective electrolytes having different specific resistances; and
a power source for supplying a processing current between said substrate and said counter electrode.

8. The apparatus of claim 7, wherein said membrane comprises at least one of a porous membrane, a porous structural member, and an ion exchange membrane.

9. The apparatus of claim 7, wherein said electrolyte supply system for supplying said electrolyte to said counter electrode side region comprises a specific resistance detector for detecting specific resistance of electrolyte and a specific resistance adjuster for adjusting specific resistance of electrolyte based on an output of said specific resistance detector.

10. The apparatus of claim 7, wherein said substrate is set as a cathode, and wherein said counter electrode is set as an anode, and wherein said counter electrode comprises a mesh-like member made of an insoluble material.

11. The apparatus of claim 10, further comprising a gas discharge line for discharging a gas generated at said anode.
